(19) United States
(12) Patent Application Publication
(10) Pub. No.: US 2004/0266211 A1
(43) Pub. Date: Dec. 30, 2004

(54) Semiconductor interfaces

(75) Inventors: Meng Tao, Colleyville, TX (US); Wiley P. Kirk, Garland, TX (US); Xiaolong Yang, Arlington, TX (US)

Correspondence Address: THOMAS C. WRIGHT, GARDERE WYNNE SEWELL LLP, SUITE 3000, 1601 ELM STREET, DALLAS, TX, 75201-4761, US

(73) Assignee: Board of Regents, The University of Texas System, Austin, TX

(21) Appl. No.: 10/822,345

(22) Filed: Apr. 12, 2004

Related U.S. Application Data
(63) Continuation-in-part of application No. 10/377,015, filed on Feb. 28, 2003, now Pat. No. 6,784,114.

(51) Int. Cl. H01L 21/31; H01L 21/469

(52) U.S. Cl. 438/758; 438/770

(57) ABSTRACT

The present invention relates generally to compositions and methods of improving the interface between a semiconductor material and a dielectric. One method provides for a method of improving the interface between a dielectric and a semiconductor material comprising the steps of preparing a passivated semiconductor surface using a valence-mending agent, depositing a precursor to a dielectric on the valence-mended semiconductor surface and oxidizing the precursor to a dielectric, wherein depositing and oxidizing do not damage the valence-mended semiconductor surface. The present invention also includes a semiconductor/dielectric interface with improved capacitance-voltage characteristics comprising a semiconductor substrate having at least one surface with one atomic layer of valence-mending atoms and a dielectric deposited on the semiconductor substrate.

### CROSS-REFERENCE TO RELATED APPLICATIONS

This application is a continuation-in-part of U.S. patent application Ser. No. 10/377,015, filed on Feb. 28, 2003, herein incorporated by reference.

### STATEMENT REGARDING FEDERALLY SPONSORED RESEARCH OR DEVELOPMENT

The U.S. Government may own certain rights in this invention pursuant to the terms of the SRC Task No. 1054.001.

### BACKGROUND OF THE INVENTION

The present invention relates to improvements for semiconductors, and particularly to compositions and preparations for providing improved semiconductor interfaces free of dangling bonds and free of strained bonds.

Dangling bonds and strained bonds are an inherent nature of semiconductor surfaces. Dangling and strained bonds cause a variety of problems in the fabrication of solid-state devices on semiconductor substrates. At the dielectric/semiconductor interface, they are responsible for the poor electrical properties of the interface. This interface plays a critical role in the operation of virtually all semiconductor devices in service today.

To date, the interface between silicon dioxide (SiO₂) and silicon (Si) represents the best dielectric/semiconductor interface, which is the primary reason for the phenomenal success of silicon-based devices. Unfortunately, no other semiconductor shows a good-quality interface with any dielectric, including germanium, silicon-germanium, silicon carbide, gallium arsenide, indium phosphide, and gallium nitride. Next-generation silicon devices require a new dielectric material with a high dielectric constant (high-k dielectric) to replace silicon dioxide in today's silicon devices. High-k dielectric materials include hafnium dioxide (HfO₂), zirconium dioxide (ZrO₂), and their silicates and aluminates. The interface between high-k dielectric and silicon suffers the same problem other semiconductors all suffer: a poor dielectric/semiconductor interface which prevents reliable operation of the device. As such, there remains a need to improve these interfaces in order to create electrical components with good electrical properties.

With such problems, no currently available method effectively improves the dielectric/semiconductor interface, so that a good-quality interface can be realized in a number of dielectric/semiconductor interfaces, including the high-k/silicon interface. Therefore, there exists a need for an effective method of passivating a semiconductor while concomitantly minimizing any carry over effects from the passivation itself.

### SUMMARY OF THE INVENTION

The present invention provides for a passivated semiconductor surface free of dangling bonds and free of strained bonds by creating a valence-mended semiconductor surface. Because the thickness of the passivation layer is precisely controlled (generally to one atomic layer, equivalent to at least about one Angstrom thick), the passivated surface is capable of keeping its semiconducting nature. A dielectric film is applied on top of the valence-mended semiconductor surface. The resultant dielectric-semiconductor interface shows excellent electrical properties, comparable to a silicon dioxide-silicon interface. Various semiconductor devices are manufactured taking advantage of this excellent dielectric-semiconductor interface.

In one form, the present invention is a method of improving the interface between a dielectric and a semiconductor material comprising the steps of preparing a passivated semiconductor surface using a valence-mending agent, depositing a precursor to a high dielectric constant material on the valence-mended semiconductor surface and oxidizing the precursor to a high dielectric constant material, wherein depositing and oxidizing do not damage the valence-mended semiconductor surface. As used herein, a semiconductor surface may be selected from those known to one of ordinary skill in the art, wherein at least one surface is available for preparing and depositing. Similarly, as used herein, a passivating agent is generally a Group VI element, but may include those from other Groups. In addition, as used herein, a valence-mended semiconductor surface is one atomic layer thick. Likewise, a high dielectric constant material and its precursors generally include a metal selected from those used with semiconductor devices and the dielectric may be a high-constant dielectric with a dielectric constant larger than 4. Oxidizing, as described herein, may include a variety of methods, temperatures, pressures and durations, depending on the dielectric. Those skilled in the art will be able to determine such variations with ease.

In still another form, the present invention is a method of improving the interface between a metal and a silicon (100) surface comprising the steps of passivating the silicon (100) surface using a Group IV element (passivating agent), depositing a film of metal on the silicon (100) surface and oxidizing the metal film to convert the metal film to a metal oxide film which is a dielectric.

Still another form of the present invention provides a method of improving the interface between a metal and a silicon-germanium (100) surface comprising the steps of passivating the silicon-germanium (100) surface using a Group IV element (passivating agent), depositing a film of metal on the silicon-germanium (100) surface and oxidizing the metal film to convert the metal film to a metal oxide film. Depositing and oxidizing do not damage the passivated silicon-germanium (100) surface.

In yet another form, the present invention is a semiconductor-dielectric interface with improved capacitance-voltage characteristics comprising a semiconductor substrate having at least one surface with one atomic layer of valence-mending atoms (provided by preparing the substrate with a passivating agent) and a dielectric film deposited on the passivated semiconductor surface.

One advantage of the present invention is that the passivation layer formed by the passivating agent is small enough (a monolayer often about one Angstrom thick) that the semiconductor surface still exhibits semiconducting properties. Passivation saturates dangling bonds and relaxes strained bonds on the semiconductor surface. As such, following deposition of a dielectric, the dielectric/semiconductor interface is of excellent quality allowing for the production of semiconductor devices not possible in the past. For example, the resultant dielectric/semiconductor interface has excellent electrical properties, comparable if not better than a silicon dioxide/silicon interface. Various new semiconductor devices may be manufactured as a result of the present invention.

Those skilled in the art will further appreciate the above-noted features and advantages of the invention together with other important aspects thereof upon reading the detailed description that follows in conjunction with the drawings.

### BRIEF DESCRIPTION OF THE FIGURES

For more complete understanding of the features and advantages of the present invention, reference is now made to the detailed description of the invention along with the accompanying FIGURES, wherein:

FIG. 1 depicts the atomic structure of a nascent silicon (100) surface with (A) side view into the [011] direction and (B) top view into the [100] direction, wherein dark circles are surface atoms, open circles are second-layer atoms, third, fourth, and fifth layer atoms are gray circles, and each surface atom has two dangling bonds;

FIG. 2 depicts a side view into the [011] direction of (A) a reconstructed silicon (001) surface and (B) a Group VI-passivated silicon (001) surface, wherein dark circles represent surface silicon atoms, white circles are second layer atoms and gray circles are bulk atoms;

FIG. 3 depicts an atomic structure of a passivated silicon (100) surface with a monolayer of sulfur, selenium, or tellurium with (A) side view into the [011] direction and (B) top view into the [100] direction, wherein hatched circles are Group VI atoms and the passivated surface has no dangling bonds;

FIG. 4 depicts the phase behavior of sulfur, selenium and tellurium as a function of temperature and pressure;

FIG. 5 depicts capacitance-voltage characteristics of the interface between hafnium dioxide and silicon (100) surface with and without selenium passivation of the silicon surface, wherein the hafnium film is deposited by electron-beam evaporation and then oxidized to form hafnium dioxide;

FIG. 6 depicts the observed pressure of selenium during the passivation of silicon by molecular beam epitaxy in accordance with the present invention;

FIG. 7 depicts current-voltage characteristics of (a) as-deposited magnesium contacts and (b) annealed magnesium contacts at 300 degrees Centigrade in a nitrogen ambient for 30 seconds;

FIG. 8 is a band diagram of magnesium/silicon contacts (A) without interface states and (b) with interface states; and

FIG. 9 is the rectification ratio (I_{f}/Iᵣ at V=±0.3 V) as a function of annealing temperature for magnesium contacts on hydrogen-passivated and selenium-passivated silicon (100).

### DETAILED DESCRIPTION OF THE INVENTION

The invention, as defined by the claims, may be better understood by reference to the following detailed description. The description is meant to be read with reference to the figures contained herein. This detailed description relates to examples of the claimed subject matter for illustrative purposes, and is in no way meant to limit the scope of the invention. The specific aspects and embodiments discussed herein are merely illustrative of ways to make and use the invention, and do not limit the scope of the invention.

Dangling and/or strained bonds are responsible for several adverse conditions that occur on a semiconductor surface, such as increasing chemical reactivity of the surface by acting as reaction sites for chemical reactions and creating surface states that cause the observed properties of electronic devices to vary from their design specifications. On a semiconductor surface, dangling bonds adsorb oxygen, water, or carbon dioxide, and a layer of native oxide is formed as soon as the surface is exposed to air.

Traditionally, the passivation of semiconductor surfaces has been realized with a thin layer of a dielectric, such as silicon dioxide (SiO₂) or silicon nitride (Si₃N₄) prepared by oxidation, chemical vapor deposition or physical vapor deposition. Unfortunately, the thickness of the passivation layer is typically a few nanometer (nm) to a few micrometers (μm). As such, the semiconductor surface covered with a dielectric of such a thickness no longer behaves as a semiconducting surface, but an insulating one.

Other methods that have been used over the years to attempt to reduce or passivate surface states on semiconductor substrates often impede the ability of solid-state devices to behave as they are designed. For example, an alternative method to passivate semiconductor surfaces, hydrogen passivation, often breaks down in air after a short period of time (minutes). This method relies on converting semiconductor-hydrogen bonds from dangling semiconductor bonds, but suffers from steric problems due to the fact that there is insufficient room to break up the dimer bonds and fully hydrogenate the silicon (100) surface. As a result, there are still surface effects that detract from the performance of any semiconductor devices ultimately formed on such a substrate.

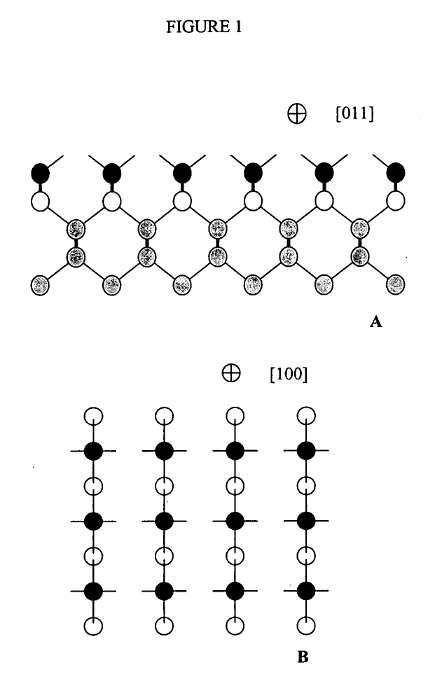

A semiconductor surface is where chemical bonds are broken and dangling bonds are created. For example, each surface atom on the (100) surface of silicon has two dangling bonds, as shown in FIG. 1, which make the surface electrically and chemically reactive. When the surface is exposed to air, the dangling bonds quickly react with air and chemically adsorb molecules or species from the air: water (H₂O), carbon dioxide (CO₂), oxygen (O₂), etc. When the surface is in contact with other materials such as metals or metal oxides, interfacial reactions take place, which form an interfacial layer of silicide or oxide with or without heating.

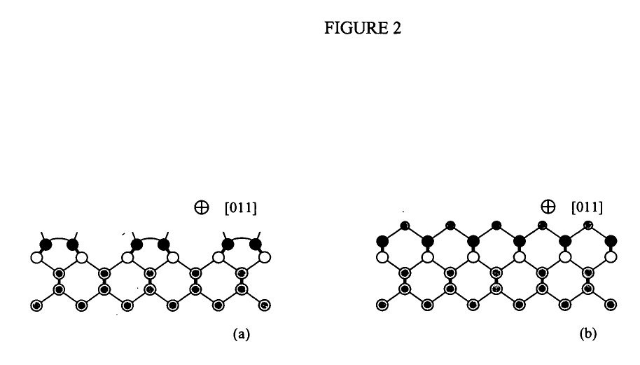

When a clean silicon (100) surface is kept in ultrahigh vacuum, it has little chance for adsorption or reaction with external species. Under such conditions, the surface undergoes reconstruction to reduce its energy. Each atom on a reconstructed silicon (100): 2×1 surface has one dangling bond and shares a dimer bond with a neighboring surface atom, as shown in FIG. 2(a). Electrically, surface states originate from dangling bonds and strained surface bonds (i.e., dimer bonds and back bonds) and often pin the surface Fermi level, causing surface band bending. When a metal is deposited on the silicon (100) surface, surface states (now more appropriately, interface states) pin the interface Fermi level, making the Schottky barrier height less dependent on metal work function and semiconductor electron affinity and instead, the barrier height is controlled by surface states.

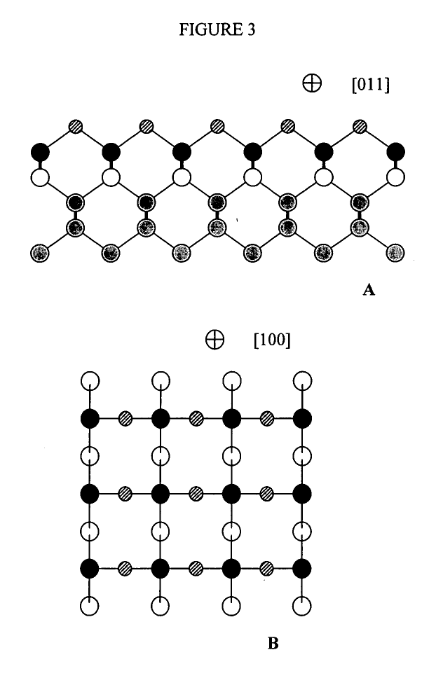

To eliminate dangling bonds on semiconductor surfaces, the present invention provides for a method of preparing a very thin layer of valence-mending atoms on a semiconductor surface. In one embodiment, the thin layer is precisely one atomic layer. For a silicon (100) surface, valence-mending atoms include most of the Group-VI elements, such as sulfur (S), selenium (Se), and tellurium (Te). An example of the atomic structure of a valence-mended silicon (100) surface is shown in FIG. 3.

The concept of “valence-mending” was proposed to eliminate dangling bonds on semiconductor surfaces. For the silicon (100) surface, valence-mending atoms include Group VI atoms sulfur (S), selenium (Se) and tellurium (Te). They can bridge between two surface atoms and nicely terminate dangling bonds and relax strained bonds on silicon (100), as shown in FIG. 2(b). This structure is often noted as a 1×1 reconstruction. The difficulty with valence mending is controlling the amount of passivating agent that is incorporated so that a new layer of material that significantly interferes with the intrinsic properties of the semiconductor substrate is not built up.

Today, 95% of all semiconductor devices are field effect transistors (FETs). These are not the transistors, however, that Bardeen first demonstrated in 1947. The first example of a solid-state device was a point contact transistor that was less subject to the problems inherent in the formation of an FET. The difficulty in preparing an FET arose from problems caused by surface effects or surface states in the semiconductor material. The surface states were a direct result of dangling bonds on the surface of the semiconductor.

The present invention provides, for example, a method for passivating the surface of a semiconductor without substantially altering the properties of the underlying material. As a result, solid-state devices that have been passivated in accordance with the present invention display greatly lowered Schottky barriers, or alternatively, improved ohmic contacts. Before the use of the present invention, no metal/semiconductor interface was observed to have a Schottky barrier of less than 0.4 electron volts on n-type silicon. For example, the reported Schottky barrier value of aluminum/silicon contacts is 0.7 electron volts. This is contrasted with the aluminum/silicon contacts in accordance with the present invention that exhibit Schottky barriers of 0.06 to 0.1 electron volts, values much closer to the theoretical value of −0.01 than previously observed. Similarly, chromium/silicon contacts have been reported to have Schottky barriers of 0.61 electron volts. When chromium/silicon contacts are prepared in accordance with the present invention the observed barrier is 0.25 electron volts, which is very close to the theoretical barrier height of 0.21 electron volts.

The present invention may also be used to prepare ohmic contacts i.e., a metal/semiconductor with a negative Schottky barrier, or put another way, no Schottky barrier at all. Both magnesium and titanium contacts with silicon have been reported to display Schottky barriers. When these contacts are prepared on surfaces that have been passivated in accordance with the present invention, they become ohmic, i.e., they display no barriers. This is demonstrative of the powerful effects of surface states and the desirability of removing such states from surfaces on which solid-state devices are constructed.

The present invention involves the application of a passivating agent, also referred to as a passivant, under conditions that allow the passivant to react with a semiconductor surface but not to agglomerate or otherwise condense to form a thicker layer. In one form, this is accomplished by adjusting the temperature and pressure such that the partial pressure of the passivating agent is below the pressure at which it can condense. Under these conditions the passivant may react when it actually contacts the semiconductor substrate and in so doing forms a monolayer of material across the surface. Once the monolayer is complete no further deposition may take place. Since condensation is also precluded, the substrate may only exist in a monolayer passivated form.

The present invention may be used with a variety of passivants of varying valence. For example, the congeners of Groups VI in the periodic table may be used to passivate the silicon (100) surface by bridging between surface atoms and eliminating dangling bonds, dimer bonds and strained back bonds. For other semiconductor surface morphologies such as atomic steps, monovalent materials such as halogens of Group VII and hydrogen and its isotopes may be used to passivate those areas of the semiconductor surface.

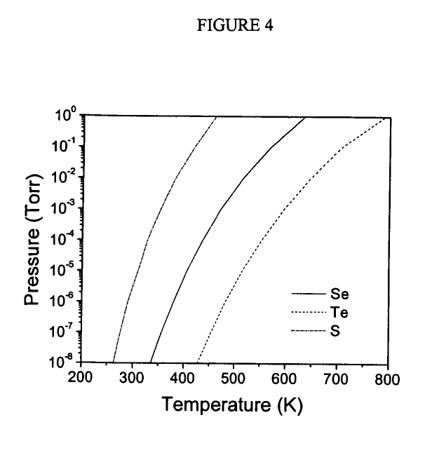

FIG. 4 depicts the known condensation behavior of the Group VI elements, sulfur, selenium and tellurium as a function of pressure and temperature. The line for each element indicates where the condensed and vapor states of the element are in equilibrium with one another. Under conditions to the left of a chosen line in the plot, condensation will occur, and to the right of the same line, the element exists only in its vapor state. The present invention makes use of this data by using conditions where the element only exits in the vapor phase and allowing it to interact with a semiconductor substrate. The gaseous element may only be permanently removed from the vapor phase by contacting the surface and reacting with it. This is how monolayer passivation is accomplished.

The present invention, thus, provides for methods of suppressing the chemical reactivity of a semiconductor surface by eliminating dangling and strained bonds on its surface. As presented herein, this is achieved by passivating one or more dangling bonds with a very thin layer of valence-mending atoms deposited onto the surface. Generally, the thin layer (monolayer) is precisely one atomic layer.

In one embodiment, the present invention addresses problems associated with a poor dielectric/semiconductor interface, including those found with materials such as silicon, germanium, and other Group IV semiconductors. The method eliminated dangling bonds on the (100) surface of the semiconductors with the addition of a monolayer of valence-mending atoms on the surface. Such valence-mending atoms include Group VI atoms, such as sulfur, selenium, and tellurium. A thin film of a dielectric or a precursor to a dielectric was then prepared on the valence-mended (passivated) semiconductor surface. As such, electrical properties of a dielectric/semiconductor interface were improved significantly.

For Group III-V compound semiconductors (e.g, gallium arsenide), passivation of the (100) surface is often attempted with sulfur, which is not very effective. In addition, if the dielectric to be used on the sulfur-passivated surface is an oxide, the interface is thermodynamically unstable. The present invention takes into account such thermodynamics and employs a non-oxide dielectric for valence-mended Group III-V compound semiconductors.

In another embodiment, the present invention improves the interface between silicon and high-k dielectrics. Silicon complimentary metal-oxide-semiconductor (CMOS) devices account for over 90% of the $200 billion semiconductor industry. Continued reduction of the gate length of silicon CMOS devices requires the gate oxide (SiO₂) thickness to be reduced to less than 15 Angstroms. A critical problem with such a thin gate oxide is the enormous leakage current through the gate oxide, which dramatically increases the standby power consumption of the integrated circuit. A new dielectric material with a high dielectric constant (high-k dielectrics), such as hafnium dioxide (HfO₂), zirconium dioxide (ZrO₂), and their silicates and aluminates, is needed for next generation devices.

As such, next-generation silicon CMOS devices must employ a new dielectric material with a high dielectric constant to replace silicon dioxide. Unfortunately, the interface between silicon and high-k dielectric is far inferior to the interface between silicon and silicon dioxide. The poor high-k dielectric/silicon interface has postponed the implementation of high-k dielectrics in silicon device manufacturing. Moreover, no semiconductors other than silicon have shown good-quality interfaces with any dielectrics. A good example is silicon CMOS devices with a strained silicon-germanium (SiGe) channel for carrier mobility enhancement. The silicon-germanium layer often has to be physically separated from the gate oxide since the SiO₂/SiGe interface is inferior to the SiO₂/silicon interface.

To reduce the gate leakage current, high-k dielectrics have been projected to replace the SiO₂-based gate dielectric in silicon CMOS devices. Unfortunately, when a high-k dielectric such as hafnium dioxide (HfO₂) is in contact with silicon, an interfacial oxide of a few Angstroms with a low dielectric constant is often formed between HfO₂ and silicon after annealing. This interfacial oxide defeats the very purpose of using a high-k dielectric material to replace the low dielectric constant SiO₂ as the gate dielectric. The present invention is able to suppress the interfacial reaction between a high-k dielectric and silicon to obtain a thin gate dielectric of 1 nm or less. By improving the high-k dielectric/silicon interface, the present invention makes such materials suitable for device applications.

Advanced silicon devices will also employ advanced semiconductor materials such as silicon-germanium, silicon carbide, and even pure germanium. To date, none of these semiconductor materials exhibit a good-quality interface with any dielectric. The present invention provides methods to improve the dielectric/semiconductor interface, allowing a suitable interface for various devices manufactured on these semiconductors, including CMOS devices and bipolar junction devices.

Metal-oxide-semiconductors (MOS) are used as high-performance semiconductors, and include materials such as gallium arsenide, indium phosphide, and gallium nitride. Their value is in their generally superior properties over silicon. For example, their carrier mobility is much higher than that in silicon, which allows for higher-speed devices that are much faster than silicon devices. These semiconductors often offer a direct bandgap, which allows both microelectronic and optoelectronic devices to be manufactured on the same semiconductor. Unfortunately, the poor interface between these materials and any dielectric has hindered the manufacturing of MOS devices on these semiconductors. The present invention solves such problems by providing methods of preparing good-quality dielectric/semiconductor interface on these semiconductors and, therefore, allowing for the manufacture of MOS devices.

For semiconductors to use high-k dielectrics, interface traps between high-k dielectrics and silicon must be overcome. A high density of interface traps pins the interface Fermi level, and thus the threshold voltage of the silicon CMOS devices. Degradation of charge carrier mobility in silicon CMOS devices (channel mobility degradation) is partially due to carrier scattering by interface traps. The interface between thermally oxidized SiO₂ and silicon (100) surface represents the best dielectric/semiconductor interface known to us, with an interface trap density of low 10¹⁰ cm⁻² eV⁻¹. No deposited dielectric has shown a comparable-quality interface with silicon. Interface traps arise from dangling bonds at the high-k dielectric/silicon interface and, unfortunately, are an inherent feature of any dielectric/semiconductor interface. If interface traps are minimized, the interface Fermi level will be freed and channel mobility will be improved. Example Preparation: High-K Dielectric on Silicon (100) Surface

For a semiconductor such as silicon, each surface atom on the (100) surface possesses two dangling bonds that may contribute to interface traps when the surface is in contact with a dielectric. For the silicon (100) surface, valence-mending atoms generally used include sulfur, selenium, and tellurium, all of which are Group VI elements. A film of dielectric was then prepared on the valence-mended semiconductor surface in order to improve the dielectric/semiconductor interface.

One factor in the successful preparation of a film of dielectric on a valence-mended semiconductor surface is to preserve the passivated surface from damage. For example, selenium atoms passivating a silicon (100) surface have two bonds with the surface, with a bond strength of about 3 electron volts per bond. These selenium atoms can easily be removed from the surface if they are exposed to energetic particles, such as ions and electrons in a plasma process. A number of ‘soft’ methods to prepare a film of dielectric on the valence-mended semiconductor surface are known to one of ordinary skill in the art, one of which is further described, herein.

A film of metal, such as hafnium or zirconium, was deposited by electron-beam evaporation on a valence-mended silicon (100) surface (substrate). The thickness of the metal film is determined by the required thickness of the final dielectric film. The silicon substrate may be at room temperature or at an elevated temperature such as 100 to 500 degrees Centigrade. After metal deposition, the metal film was oxidized in an oxygen-containing ambient, such as pure oxygen (O₂), a mixture of oxygen and hydrogen (O₂+H₂), water vapor (H₂O), a mixture of oxygen and nitrogen (O₂+N₂), nitric oxide or nitrous oxide (NO or N₂O), ozone (Og), etc. The temperature of the oxidation process may be from 100 to 800 degrees Centigrade, depending on the metal used and the valence-mending atoms used. The duration of oxidation may be from a few seconds to a few hours, and the pressure of oxidation may be from a few milli-Torr to atmospheric pressure (760 Torr). The oxidation step converts the metal film into a metal oxide film, which is a dielectric. Since both the deposition process and oxidation process are ‘soft,’ no damage was done to the valence-mended silicon (100) surface.

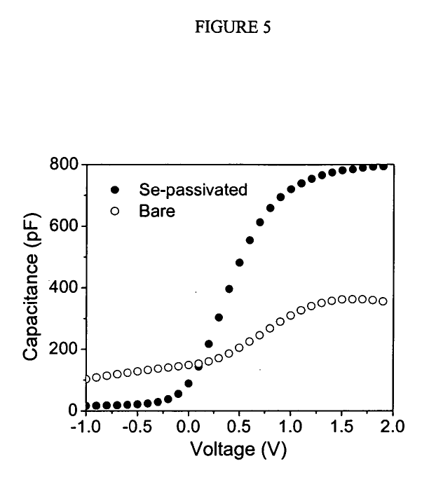

When such a method was used to prepare hafnium dioxide on selenium-passivated silicon (100) surface, significant improvement in capacitance-voltage characteristics of the high-k dielectric/silicon (100) interface were observed, an example of which is shown in FIG. 5.

Example Preparation: Dielectric/Silicon-Germanium Interface Improvement

The (100) surface of silicon-germanium, silicon carbide, or germanium was valence-mended by a monolayer of Group VI atoms. A film of metal was prepared on the valence-mended semiconductor surface and then oxidized to form a metal oxide dielectric film with good interface properties. (Data not shown.)

Preparative Examples of Valence Mending

Various features of the present invention take advantage of a method of preparing a monolayer of valence-mending atoms on a semiconductor surface. Generally, the monolayer is precisely one atomic layer. Further discussion of this method is provided below. Examples are provided for a metal/silicon (100) interface with a monolayer of selenium. As described herein, low Shottky barriers were obtained on n-type silicon (100), and a negative Schottky barrier was demonstrated on n-type silicon (100) with a metal, such as magnesium or titanium.

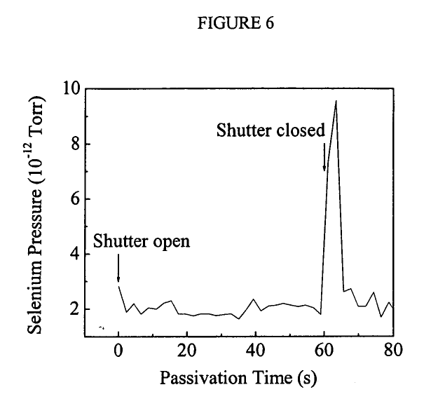

FIG. 6 graphically depicts a passivant reacting with a semiconductor surface until all of the reaction sites on the surface are passivated. With a molecular beam epitaxy (MBE) system, the shutter to a selenium source was opened at time 0 in the plot. The pressure of selenium in the reaction chamber remained low for approximately 60 seconds, indicating that the selenium was reacting with the surface and not building up in the reactor. At approximately 60 seconds, there was a spike in selenium pressure indicating that all of the reactive site on the surface of the silicon wafer were passivated, and all additional selenium that was added was merely surplus and building up as a gas in the reaction chamber.

N-type silicon (100) wafers were used with antimony doping levels in the low 10¹⁵ cm⁻³. The nominal wafer miscut was less than 0.5 degrees. The selenium passivation experiments were performed in two molecular beam epitaxy (MBE) systems connected through an ultrahigh vacuum transfer tube. One of them was for silicon growth and the other for selenium passivation. The wafers were cleaned in 2% hydrofluoric acid for 30 seconds before loaded into the silicon MBE system. Silicon buffer layers of 500 Å with residual antimony doping levels of mid-10¹⁴ cm⁻³ were grown at about 600 degrees Centigrade and then annealed at about 800 degrees Centigrade for 1 hour. Sharp 2×1 reconstruction was always obtained with reflection high-energy electron diffraction after annealing. Some wafers were unloaded after silicon buffer growth. Other wafers were transferred to the selenium MBE system for passivation. The selenium source temperature was about 224 degrees Centigrade, the passivation time was 60 seconds, and the silicon wafer temperature was 300 degrees Centigrade. Under the conditions described, precisely one monolayer of selenium was deposited on the silicon (100) surface.

After passivation, metal/silicon contacts were fabricated by electron-beam evaporation and lift-off on selenium-passivated wafers without any cleaning. The metal (such as magnesium) dots were approximately 290 μm in diameter. Metal/silicon contacts were also fabricated on silicon wafers with 500 Å silicon buffer but without selenium passivation. Heating of the metal-silicon contacts was performed with rapid thermal annealing and hot plate.

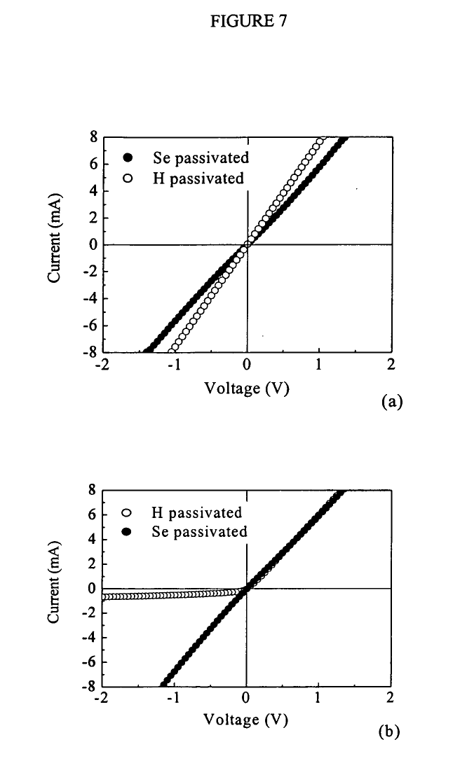

Magnesium is known to form a Schottky contact with n-type silicon (100) with a barrier height of 0.4 eV. FIG. 7(a) shows the current-voltage (I-V) characteristics of as-deposited magnesium contacts on hydrogen-passivated and selenium-passivated silicon (100) without heating, both of which behave in an ohmic fashion. In fact, ohmic behavior is observed for magnesium contacts on hydrogen-passivated and selenium-passivated silicon (100) with n-type doping levels from low 10¹⁴ cm⁻³ to high 10¹⁸ cm⁻³.

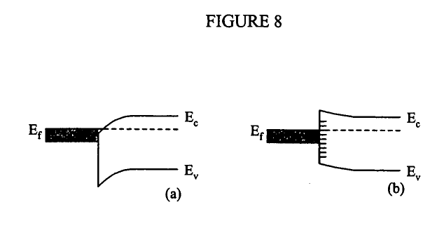

The work function, φ, of magnesium is 3.66 eV, and the electron affinity, χ, of silicon is 4.05 eV. The ideal Schottky barrier height, φ_{B}, for a magnesium/silicon contact free of interface states is φ_{B}=φ−χ, which results in a negative barrier height of −0.39 eV. The negative sign simply means that there is no energy barrier between magnesium and silicon, as shown in FIG. 8(a). In reality, interface states often pin the interface Fermi level, consistent with the band diagram in FIG. 8(b). Several metals, including most of the Groups I and II elements, can have the band diagram shown in FIG. 8(a) with silicon, if only their work functions are considered. However, interface states are so dominant between these materials and silicon that such behavior is typically not observed.

Ohmic behavior is expected for the band diagram in FIG. 8. For electrons drifting from magnesium to silicon in FIG. 8(a), there is a small energy hump that is typically less than a few tenths of an electron volt. Once the applied voltage exceeds it, the contact becomes completely ohmic. In many cases, they behave perfectly ohmic.

Ohmic behavior is also observed for magnesium contacts on hydrogen-passivated silicon (100), as shown in FIG. 7(a). It is believed that hydrogen passivation also reduces surface states and produces the band diagram in FIG. 8(a).

The behavior of these samples after heating is noteworthy. FIG. 7(b) shows the I-V characteristics of magnesium contacts on hydrogen-passivated and selenium-passivated silicon (100) after rapid thermal annealing at 300 degrees Centigrade for 30 seconds in a nitrogen ambient. While the selenium-passivated sample remains ohmic, the hydrogen-passivated sample turns into a Schottky contact. Selenium passivation produces a more stable surface than hydrogen passivation. This is significant because a number of heating steps are oftened required in the manufacture of complex semiconductor devices.

A first-principle analysis of surface energetics, accomplished by counting dangling bonds and taking into account bond dissociation energies, indicates that the selenium-passivated silicon (100) surface in FIG. 2(b) is 2.1×10⁻⁴ cal/cm² lower in energy than the hydrogen-passivated silicon (100): 2×1 surface. It is likely that hydrogen passivation breaks down and magnesium reacts with silicon to form magnesium silicide at 300 degrees Centigrade. A Schottky contact is then formed between silicon and magnesium silicide. For the selenium-passivated sample, silicide formation is suppressed and the interface remains a magnesium/silicon one at 300 degrees Centigrade.

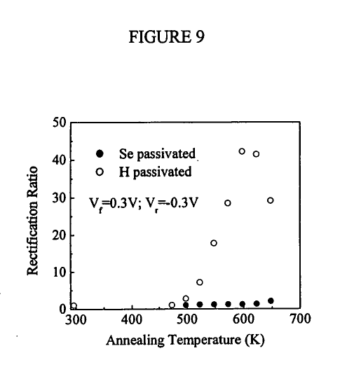

To quantify the transition from ohmic to Schottky, the rectification ratio, i.e., the ratio of the forward current, I_{f}, at forward voltage V_{f}=0.3 V and the reverse current, Iᵣ, at reverse voltage Vᵣ=−0.3 V is plotted as a function of hot-plate annealing temperature in FIG. 9 for both hydrogen-passivated and selenium-passivated silicon (100) samples. On these samples the magnesium contacts are capped with 500 Å nickel (Ni) to prevent magnesium oxidation during heating. The ratio for hydrogen-passivated samples starts to rise rapidly from ˜1 at ˜225 degrees Centigrade (500 K) and saturates to ˜40 at ˜325 degrees Centigrade (600 K). For the selenium-passivated sample, the ratio stays at ˜1 even at 375 degrees Centigrade (650 K). Annealing above 375 degrees Centigrade is difficult because even the nickel-magnesium contacts get oxidized above that temperature. It is believed that, when the annealing temperature is high enough, magnesium and selenium-passivated silicon (100) will eventually react to form magnesium silicide, and its rectification ratio will eventually increase to a value comparable to 40. If the middle point of the rectification ratio, 20, is defined as the transition temperature from ohmic to Schottky, selenium-passivated silicon (100) has a transition temperature that is more than 100 degrees Centigrade higher than that of hydrogen-passivated silicon (100) in FIG. 9. However, the same characterization has been performed on multiple samples, and the statistics indicates that the transition temperature for hydrogen-passivated samples are consistently between 275-300 degrees Centigrade, and that temperature for selenium-passivated samples fluctuates from 300 degrees Centigrade to above 375 degrees Centigrade.

In one form, a method for passivating a semiconductor surface with a thin layer or monolayer of a passivating agent (capable of providing valence-mending atoms) includes the steps of placing a semiconductor substrate, having at least one surface in a chamber, and heating the semiconductor substrate to a temperature. The semiconductor substrate is then exposed to a passivating agent for a period of time sufficient to react with substantially all of the surface, and the partial pressure of the passivating agent is such that the passivating agent will not condense at the temperature of the substrate. As a result of this treatment the presence of surface states is greatly reduced and one atomic layer of valence-mending atoms is formed on the semiconductor surface.

In another form, a method for manufacture of a semiconductor device with a low Schottky barrier includes the steps of placing a n-type semiconductor substrate having at least one surface in a chamber and heating the semiconductor substrate to a temperature. The semiconductor substrate is then exposed to a passivating agent (capable of providing valence-mending atoms) for a period of time sufficient to react with substantially all of the surface, and the partial pressure of the passivating agent is such that the passivating agent will not condense at the temperature of the substrate. As a result of this treatment the presence of surface states is greatly reduced and one atomic layer of valence-mending atoms is formed on the semiconductor surface. A portion of the semiconductor surface is then metallized with a metal having a work function whose magnitude is slightly greater than the magnitude of the electron affinity of the n-type semiconductor substrate.

In another form, a method for manufacture of a semiconductor device with a low Schottky barrier includes the steps of placing a p-type semiconductor substrate having at least one surface in a chamber and heating the semiconductor substrate to a temperature. The semiconductor substrate is then exposed to a passivating agent (capable of providing valence-mending atoms) for a period of time sufficient to react with substantially all of the surface, and the partial pressure of the passivating agent is such that the passivating agent will not condense at the temperature of the substrate. As a result of this treatment the presence of surface states is greatly reduced and one atomic layer of valence-mending atoms is formed on the semiconductor surface. A portion of the semiconductor surface is then metallized with a metal having a work function whose magnitude is slightly less than the sum of the magnitude of the electron affinity and the band gap of the p-type semiconductor substrate.

In still another form, a method for manufacture of a semiconductor device with improved ohmic contacts comprises the steps of placing an n-type semiconductor substrate having at least one surface in a chamber and heating the semiconductor substrate to a temperature. The semiconductor substrate is then exposed to a passivating agent (capable of providing valence-mending atoms) for a period of time sufficient to react with substantially all of the surface, and the partial pressure of the passivating agent is such that the passivating agent will not condense at the temperature of the substrate. As a result of this treatment the presence of surface states is greatly reduced and one atomic layer of valence-mending atoms is formed on the semiconductor surface. A portion of the semiconductor surface is then metallized with a metal having a work function whose magnitude is less than the magnitude of the electron affinity of the n-type semiconductor substrate.

In yet another form, a method for manufacture of a semiconductor device with improved ohmic contacts includes the steps of placing a p-type semiconductor substrate having at least one surface in a chamber and heating the semiconductor substrate to a temperature. The semiconductor substrate is exposed to a passivating agent (capable of providing valence-mending atoms) for a period of time sufficient to react with substantially all of the surface, and the partial pressure of the passivating agent is such that the passivating agent will not condense at the temperature of the substrate. As a result of this treatment the presence of surface states is greatly reduced and one atomic layer of valence-mending atoms is formed on the semiconductor surface. A portion of the semiconductor surface is then metallized with a metal having a work function whose magnitude is greater than the sum of the magnitude of the electron affinity and the band gap of the p-type semiconductor substrate.

While specific alternatives to steps of the invention have been described herein, additional alternatives not specifically disclosed but known in the art are intended to fall within the scope of the invention. Thus, it is understood that other applications of the present invention will be apparent to those skilled in the art upon reading the described embodiment and after consideration of the appended claims and drawing.

What is claimed is:

1. A method of improving the interface between a dielectric and a semiconductor material comprising the steps of:
preparing a passivated semiconductor surface using a valance-mending agent;
depositing a precursor to a dielectric on the valence-mended semiconductor surface; and
oxidizing the precursor to a dielectric, wherein depositing and oxidizing do not damage the valence-mended semiconductor surface.

2. The method of claim 1, wherein the precursor to a dielectric is a metal selected from the group of metals whose oxide is a dielectric.

3. The method of claim 1, wherein oxidizing is in an oxygen-containing ambient.

4. The method of claim 1, wherein the oxygen-containing ambient is selected from the group consisting of pure oxygen, an oxygen and hydrogen mixture, water vapor, an oxygen and nitrogen mixture, nitric oxide, nitrous oxide, ozone and combinations thereof.

5. The method of claim 1, wherein the semiconductor surface is selected from the group consisting of silicon, germanium, silicon-germanium and silicon-carbide.

6. The method of claim 1, wherein depositing is by evaporation selected from the group consisting of thermal evaporation and electron-beam evaporation.

7. The method of claim 1, wherein oxidizing is from a few seconds to a few hours.

8. The method of claim 1, wherein oxidizing uses a pressure from a few milli-Torr to atmospheric pressure.

9. The method of claim 1, wherein the passivating agent is selected from the group consisting of Group V, VI, or VII congener, or hydrogen.

10. The method of claim 1, wherein the valence-mended semiconductor surface is one atomic layer thick.

11. The method of claim 1, wherein during oxidizing the valence-mended semiconductor surface is at a temperature selected from room temperature to 800 degrees Centigrade, and any temperature in between.

12. The method of claim 1, wherein during depositing the valence-mended semiconductor surface is at a temperature selected from room temperature to 500 degrees Centigrade, and any temperature in between.

13. The method of claim 1, wherein the method significantly improves the capacitance-voltage characteristics of the interface between the dielectric and the valence-mended semiconductor surface.

14. A method of improving the interface between a high-k dielectric and a silicon (100) surface comprising the steps of:
passivating the silicon (100) surface using a Group VI element and hydrogen;
depositing a film of metal on the silicon (100) surface; and
oxidizing the metal film to convert the metal film to a metal oxide film with a dielectric constant larger than 4.

15. The method of claim 14, wherein oxidizing is in an oxygen-containing ambient selected from the group consisting of pure oxygen, an oxygen and hydrogen mixture, water vapor, an oxygen and nitrogen mixture, nitric oxide, nitrous oxide, ozone and combinations thereof.

16. The method of claim 14, wherein depositing and oxidizing do not damage the passivated silicon (100) surface.

17. The method of claim 14, wherein depositing is by evaporation selected from the group consisting of thermal evaporation and electron-beam evaporation.

18. The method of claim 14, wherein oxidizing is from a few seconds to a few hours.

19. The method of claim 14, wherein oxidizing uses a pressure from a few milli-Torr to atmospheric pressure.

20. The method of claim 14, wherein passivating results in a valence-mended silicon surface of one atomic layer thick.

21. A method of improving the interface between a dielectric and a silicon-germanium (100) surface comprising the steps of:
passivating the silicon-germanium (100) surface using a Group VI element and hydrogen;
depositing a film of metal on the silicon-germanium (100) surface; and
oxidizing the metal film to convert the metal film to a metal oxide film which is a dielectric.

22. The method of claim 21, wherein oxidizing is in an oxygen-containing ambient selected from the group consisting of pure oxygen, an oxygen and hydrogen mixture, water vapor, an oxygen and nitrogen mixture, nitric oxide, nitrous oxide, ozone and combinations thereof.

23. The method of claim 21, wherein depositing and oxidizing do not damage the passivated silicon-germanium (100) surface.

24. The method of claim 21, wherein depositing is by evaporation selected from the group consisting of thermal evaporation and electron-beam evaporation.

25. The method of claim 21, wherein oxidizing is from a few seconds to a few hours.

26. The method of claim 21, wherein oxidizing uses a pressure from a few milli-Torr to atmospheric pressure.

27. The method of claim 21, wherein passivating results in a valence-mended silicon-germanium surface of one atomic layer thick.

28. A semiconductor/dielectric interface with improved capacitance-voltage characteristics comprising:
a semiconductor substrate having at least one surface with one atomic layer of valence-mending atoms; and
a metal film deposited on the semiconductor substrate.

29. The semiconductor/dielectric interface of claim 28, wherein the valence-mending atoms were applied upon passivating the semiconductor substrate with an element selected from the group consisting of Group V, VI or VII elements, or hydrogen.

30. The semiconductor/dielectric interface of claim 28, wherein the semiconductor substrate is selected from the group consisting of silicon, germanium, silicon-germanium and silicon-carbide.

31. The semiconductor/dielectric interface of claim 28, wherein the metal film is oxidized to form a metal oxide dielectric film.
